(19) United States
(12) Patent Application Publication
(10) Pub. No.: US 2014/0133109 A1
(43) Pub. Date: May 15, 2014

(54) FIELD REPLACEABLE AUXILIARY SWITCH AND CONTROL CIRCUIT ASSEMBLY FOR AN ELECTRICAL CONTACTOR

(71) Applicant: DYNAPAR CORPORATION, Gurnee, IL (US)

(72) Inventors: John Marshall Thomasson, Wilmington, NC (US); Cathleen Mary Clausen, Wilmington, NC (US); Nicholas Graham Hartman, Leland, NC (US); David Donovan, Winnabow, NC (US)

(73) Assignee: DYNAPAR CORPORATION, Gurnee, IL (US)

(21) Appl. No.: 14/057,258

(22) Filed: Oct. 18, 2013

Related U.S. Application Data
(60) Provisional application No. 61/715,899, filed on Oct. 19, 2012.

(51) Int. Cl. H05K 5/00

(52) U.S. Cl. CPC H05K 5/0026
USPC 361/752

(57) ABSTRACT

A field replaceable auxiliary switch and control circuit assembly for an electrical contactor that comprises a frame member capable of being inserted into, and removable from, an opening and an interior of an electrical contactor housing. A circuit board is mounted to the frame member and has a control circuit formed thereon. The assembly may further comprise a first electrical connector disposed within the contactor housing and a second electrical connector attached to the circuit board having one or more electrical contacts capable of being positioned in mating relationship with the first electrical contactor, which is in electrical communication with an electromagnet and/or electromagnetic coil.

### CROSS-REFERENCE TO RELATED APPLICATIONS

This application claims the benefit of U.S. Provisional Application No. 61/715,899 filed Oct. 19, 2012, and incorporated herein by reference in its entirety.

### BACKGROUND OF THE INVENTION

This invention relates generally to electrical contactors and more specifically to electrical contactors that include a control circuit for switching a power circuit, and more specifically to vacuum contactors. More particularly, the invention pertains to devices or methods used to replace a control circuit and circuit board of an electrical contactor.

Prior art contactors, including vacuum contactors, have auxiliary contacts that are mounted to an exterior of the contactor housing. Control circuits are hard wired to an electro-magnetic coil using known soldering techniques. Accordingly, the circuit board and auxiliary housings protrude rendering installation of the electrical contactors cumbersome. In addition, oftentimes the control circuits or auxiliaries fail or burn out before other components of the contactor fail. It is oftentimes difficult to determine if the auxiliaries, control, circuit, or magnetic coils are the failure mode. Therefore, the entire electrical contactor is sometimes replaced. In addition, the entire unit may be replaced if it is necessary to have additional or fewer auxiliary switches to modify the switching power of the contactor, Replacement of the entire contactor increases operational costs of a power system or power grid because not only is the cost of an entire contactor unit incurred, but power is temporarily shut down in order to replace the entire unit.

### SUMMARY OF THE INVENTION

The present invention allows a failed circuit board/auxiliary switch assembly to be replaced in the field easily as one component without replacing an entire electrical contactor, or in the event that power switch capabilities must be upgraded or downgraded according to the power output demands, the integrated control circuit board is readily replaceable. A field replaceable auxiliary switch and control circuit assembly for an electrical contactor comprises a frame member that is insertable in an opening of a contactor housing and detachably secured to the contactor housing. A circuit board, having a control circuit thereon is affixed to the frame member. A first electrical connector, in electrical communication with the control circuit, is attached to the board and is configured to be connected to a second electrical connector in the housing. The second electrical connector is in electrical communication with an electro-magnetic coil and is detachably connected to the first electrical connector when the assembly is installed.

In an embodiment of the invention, the first electrical connector may be a projection on a side edge of the circuit board having one or more electrical contacts. The projection is positioned in mating relationship with the second connector which may be a socket head affixed within the contactor housing to provide electrical communication between the control circuit and the electro-magnetic coil of the electrical contactor. In another embodiment, the first connector is connected to electrical leads on the circuit board and the second connector attached to electrical wires, but is not fixed within the housing and can be picked up and manipulated to join the first and second connectors for installation of the assembly.

In addition, the frame member may have a power input terminal that is in electrical communication with the control circuit, a plurality of auxiliary switches on the circuit board that are actuated to close and open to activate and deactivate the control circuit respectively; and a plurality auxiliary terminals in electrical communication with the auxiliary switches for monitoring the power output of the contactor.

### BRIEF DESCRIPTION OF DRAWINGS

The invention is explained in the following description in view of the drawings that show:

FIG. 1 is a first perspective view of a vacuum contactor in accordance with aspects of the subject invention.

FIG. 2 is a second perspective view of the vacuum contactor of FIG. 1 with a removable auxiliary switch and control circuit assembly installed.

FIG. 3 is an exploded view of the housing of the vacuum contactor in accordance with aspects of the invention.

FIG. 4 is a side perspective view of the interior of the electrical contactor in Which the auxiliary switch and contact assembly and electro-magnetic coil is housed.

FIG. 5 is a perspective view of a first embodiment of the auxiliary switch and control circuit assembly showing the control circuit board and auxiliary switches.

FIG. 6 is a perspective view of a second embodiment of the auxiliary. control circuit assembly showing the control circuit board and auxiliary switches.

FIG. 7 is a perspective view of a second embodiment of the auxiliary switch and control circuit assembly showing the auxiliary terminals.

FIG. 8 is a perspective view of the auxiliary switch and control circuit assembly removed from the housing.

FIG. 9 is a sectional view of the electrical contactor showing the first embodiment of the auxiliary switch and control circuit installed in the contactor.

FIG. 10 is a sectional view of the electrical contactor showing the second embodiment of the auxiliary switch and control circuit installed in the contactor.

FIG. 11 is a partial exploded and perspective view of a bolt for a contact bus to be installed.

### DETAILED DESCRIPTION OF THE INVENTION

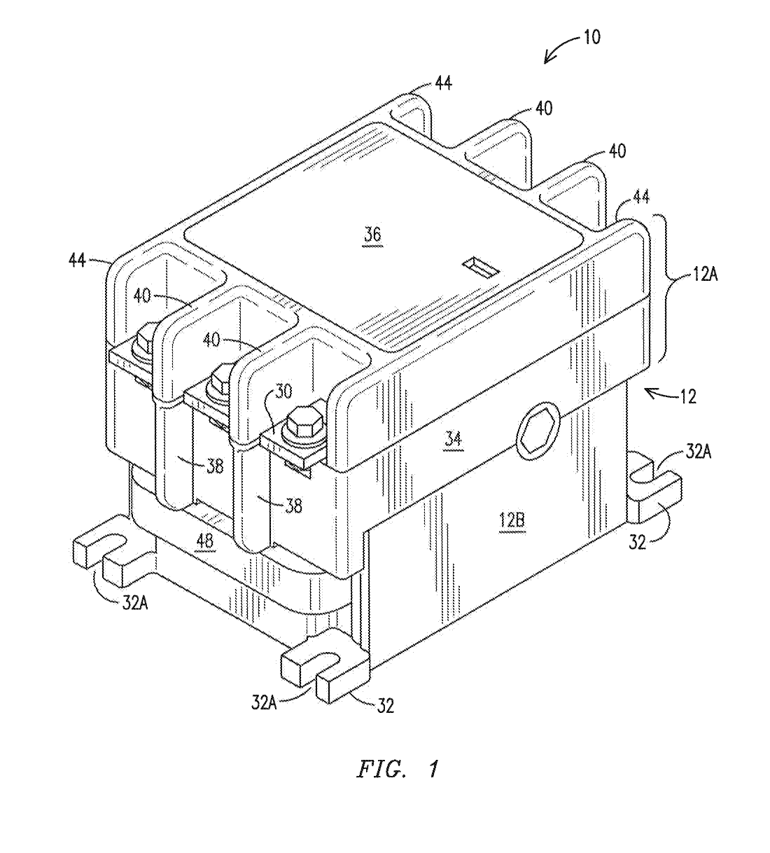

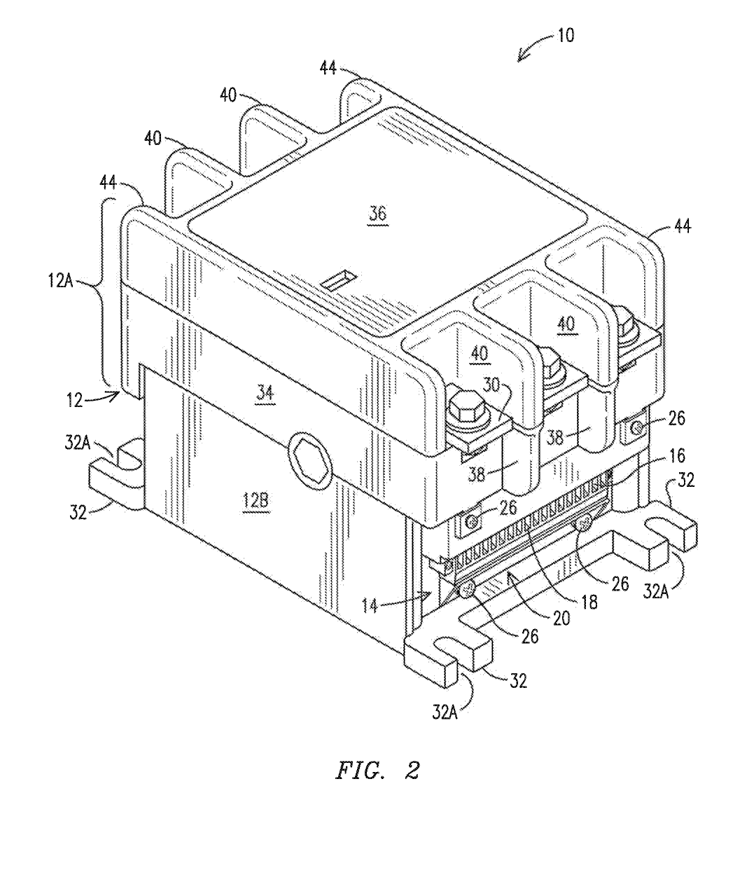

With reference to FIGS. 1 and 2, a vacuum contactor 10 is illustrated and includes a housing 12 within which components such as contact buses 30, springs, vacuum bottle assemblies 47, electro-magnetic coils 46, cores 48, etc., are housed. The housing 12 includes a first housing section 12A in which the contact buses 30 and vacuum bottle assemblies 47 are supported and a second housing section 12B in which a control circuit board 22 with a control circuit 21 (which may be an integrated control circuit) and an electro-magnetic coil 46 and core 48 are supported. The control circuit board 22 and control circuit 21 are positioned within the second section 12B of the housing 12 in electrical communication with an electro-magnetic coil 46 to open and close contact buses 30, the operation of which is known to those skilled in the art.

As shown in FIG. 2 the vacuum contactor 10 includes an auxiliary switch and control circuit assembly 14 (also referred to herein as the “assembly 14”) installed to provide power input into the vacuum contactor 10 to open and close contact buses 30 and provide auxiliary output for monitoring the operation of the vacuum contactor 10. More specifically, the contact switch assembly 14 includes a power input terminal 16 and a plurality of auxiliary terminals 18. As will be explained in more detail below, the assembly 14 is field replaceable in the event certain operating parameters relative to the vacuum contactor 10 change. For example if the switching power of the contactor 10 must he upgraded or downgraded or, for example, if the control circuit board 22 must be replaced, the assembly 14 is readily removed and replaced with another assembly.

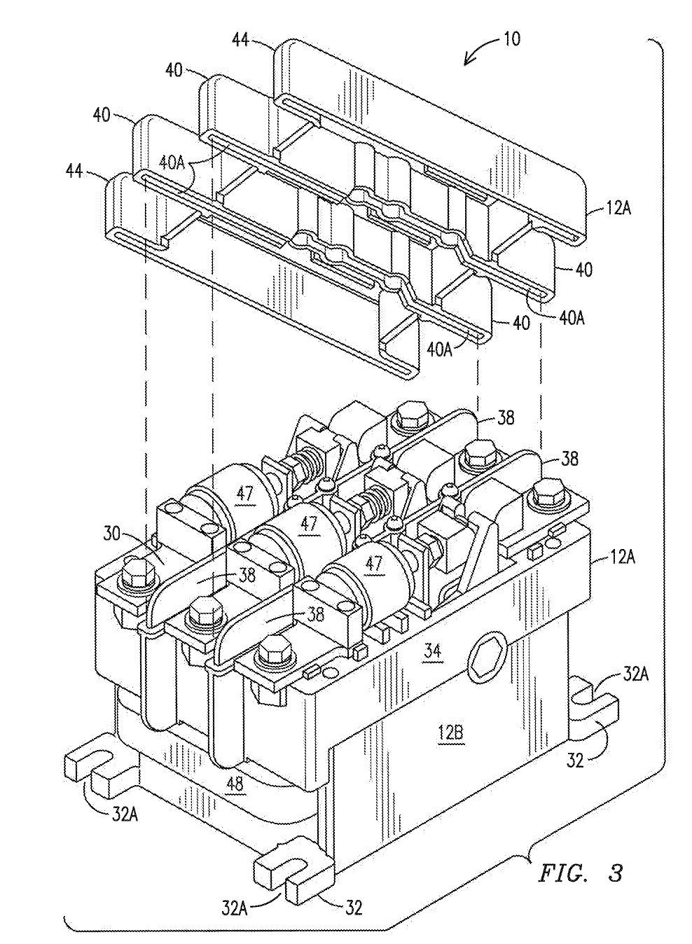

In an embodiment of the invention, the first housing section 12A includes mid-section 34 that is detachably affixed to the second housing section 12B and on which the contact buses 30 and vacuum bottle assemblies 47 are supported. The first housing section 12A also includes a cover 36 that is detachably affixed to the mid-section 34 and covers the components supported by the mid-section 34. As shown in FIG. 3, the mid-section 34 preferably includes internal panels 38 each disposed between adjacent contact buses 30. The cover 36 comprises internal panels 40 which include channels 40A configured to receive the panels 38, on mid-section 34 when the cover 36 is installed. As further shown in FIGS. 1-4, the cover 36 also includes outer panels 44, which are shorter in length to the internal panels 40 the advantage of which is explained in more detail in reference to installation of the vacuum contactor 10.

Note, in an embodiment all components of the housing 12, including the first housing section 12A (mid-section 34, cover 36 and panels 38, 40) and the second housing section 12B are composed of a glass filled thermoset material, such as a 30% glass-filled polyester thermoset, which provides electrical insulating and temperature insulating properties. The housing 12, and its components, may be manufactured using known molding processes such as injection molding, spin molding, extrusion molding, etc.

As also shown in FIGS. 1-3, the second housing section 12B includes foot mounts 32 (also referred to as brackets), which are configured to receive fasteners, such as bolts, in slots 32A to affix the vacuum contactor 10 to a surface for installation. The foot mounts 32 may be integrally formed with the second housing section 12B. Alternatively, the foot mounts 32 may be part of a separate component that forms a base of the second housing section 12B. In addition, end panels 44 on the cover 36 are shorter in length than panels 40 and generally flush with ends of the mid-section 34. With such a configuration, a user may more readily access the fasteners at the foot mounts 32 with tools for installation or removal of the contactor 10. In addition, a portion of each foot mount 32 is laterally offset relative to sides of the housing 12 to provide set spacing between adjacent contactors 10. In addition, the foot mounts 32 have slots 32A, which configuration allows for mounting clearance.

With respect to FIG. 4, the mid-section 34 and cover are shown removed illustrating a mechanical lever 55 supported by the second housing section 1213. The lever 55 is rotatable in the housing 12 and is operatively connected to the vacuum bottle assemblies 47 and/or contact buses, which open and close when power is input to the contactor 10. The movement of the contact buses 30 causes the lever to pivot and contact the auxiliary switches 24 to close or pivots to open the switches 24 responsive to movement of the contact buses 30.

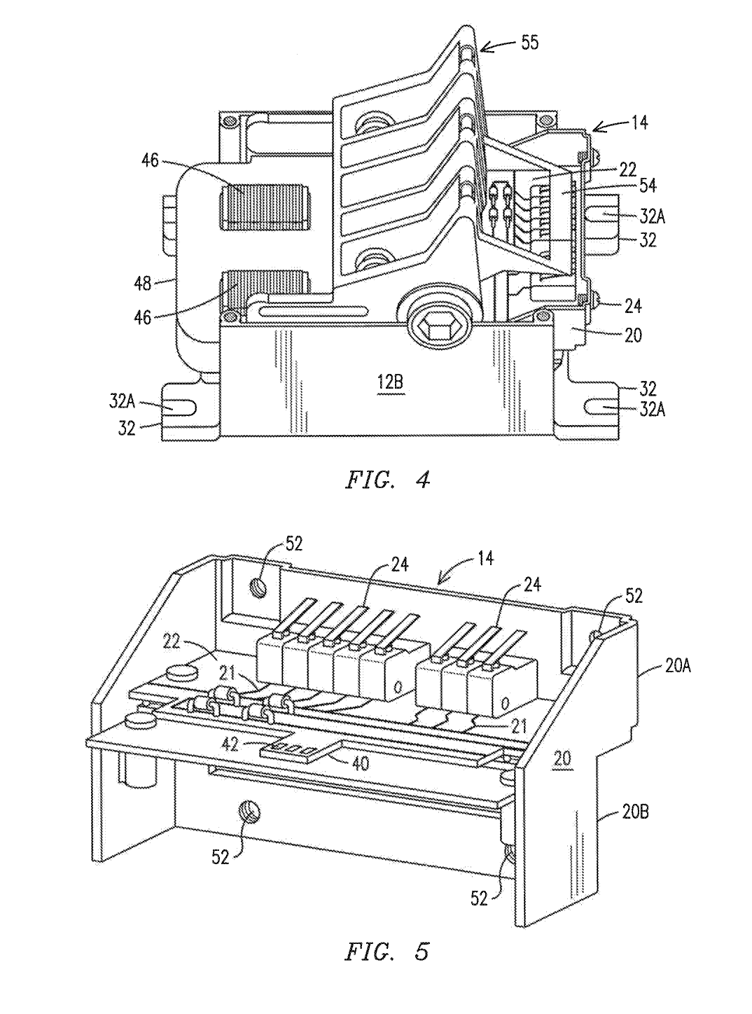

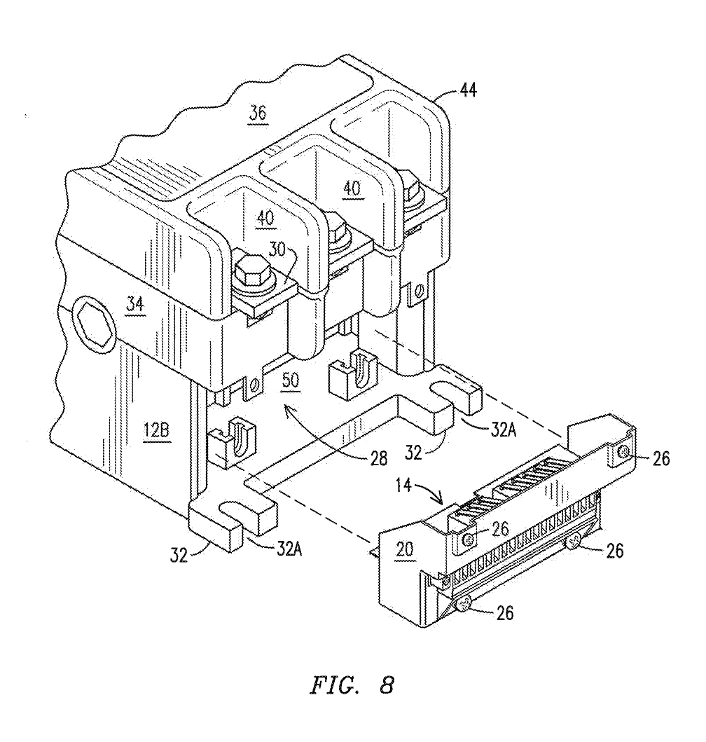

With respect to FIGS. 5-7, the contact switch assembly 14 includes a support frame 20 on which components of the assembly 14 are mounted. In addition to supporting the terminals 16 and 18, the control circuit board 22 and auxiliary switches 24 are mounted to the support frame 20. Fasteners 26 (FIG. 2), such as bolts, secure the assembly 14 to the housing 12. Although not shown in detail, a control board 22 includes a control circuit 21 that controls the power output of the vacuum contactor 10 as well as the auxiliary output for monitoring purposes. Such circuits may sometimes be referred to those skilled in the art as economizer circuits, the design and function of which are known to those skilled in the art.

To that end, as shown in FIGS. 8-10 when the housing 12 is completely assembly an opening 28 exists between the housing mid-section 34 and the second housing section 12B, which together at least partially define an interior volume 50 to the housing 12 that is disposed between the opening 28 and electro-magnetic coil 46 and in which the assembly 14 is inserted. Holes 52 on the support frame 20 are aligned with holes on the second housing section 12B to receive fasteners 26 to secure the support frame 14 and the components thereon to the housing 12. The frame 20 is dimensioned relative to the second housing section 12B to snugly fit within the volume of the housing section 12B and abut interior positioning surfaces of the second housing 12B.

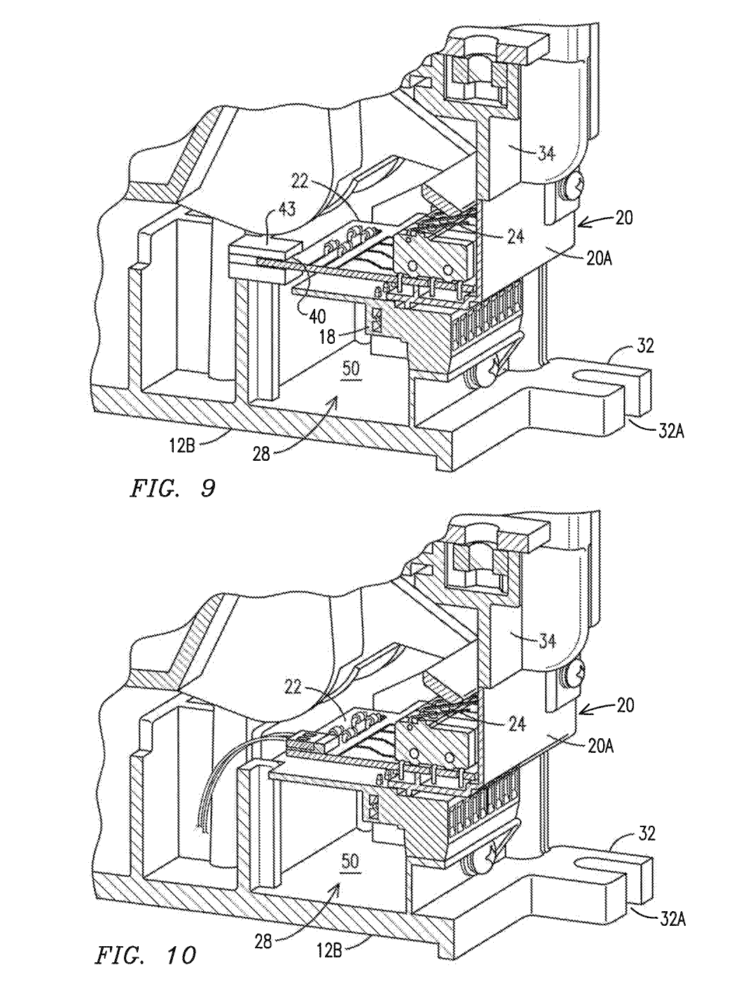

As shown in FIG. 5, in one embodiment of the invention the circuit board 22 includes a plug 40, or projection (which may also be referred to as an electrical connector or second electrical), that is disposed on a side edge of the board 22 and includes one or more electrical contacts 42 to provide electrical communication between the control circuit 21 on the board 22 and the electric-magnetic coil 46 that when energized or de-energized opens and closes the contact buses 30, respectively. More specifically, and as shown in FIG. 9, when the assembly 14 is inserted into the housing 12, or second housing section 12B, the plug 40 is aligned with and positioned in mating relationship with a socket or header 43 (first electrical connector), which is mounted in a fixed position within the housing 12. This header 43 includes corresponding electrical contacts and connecting wires to electrically interconnect the control circuit 21 to the electromagnet and/or electro-magnetic coil 46.

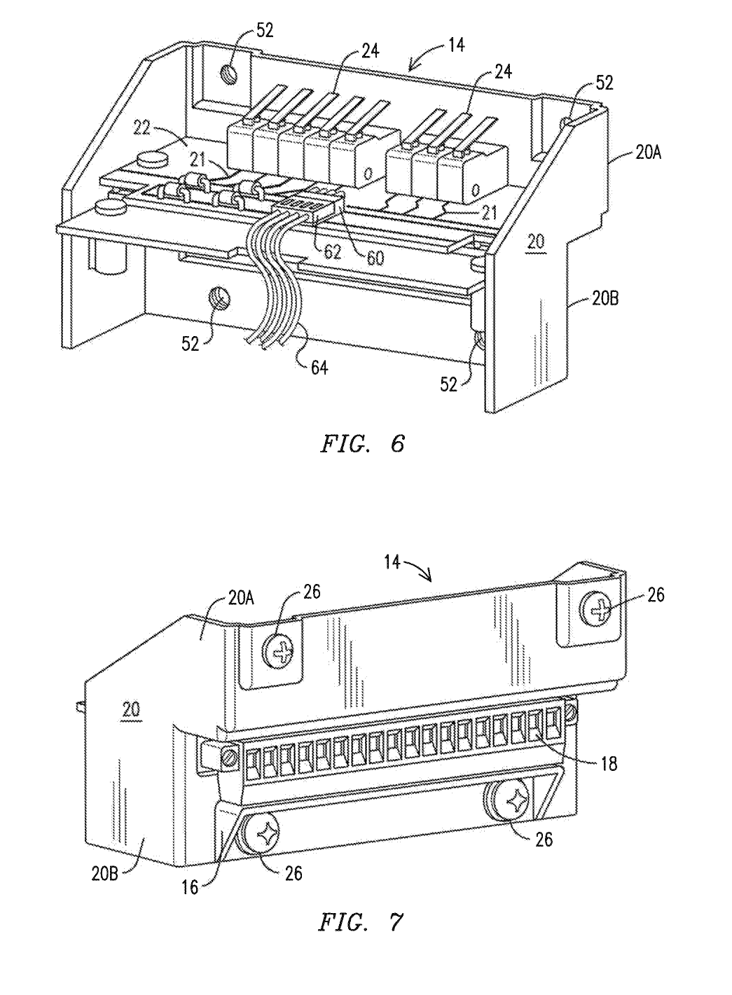

In another embodiment shown in FIG. 6, a first electrical connector 62 is disposed within the housing 12 and is attached to electrical wires 64 which in turn are connected to the electromagnetic coil 46. The assembly 14 includes a second electrical connector 60 connected to electrical leads on the circuit board 22. In this embodiment, when the assembly 14 is installed an operator simply grasps the first connector 62, and because it is not fixed to a surface of the housing, the operator can mate or join the first and second connectors 62, 60 and insert the assembly 14 into housing 12 at the opening 28.

In the event that the control circuit 21, or other components of the contact switch assembly, fails or is in a condition that may deleteriously affect the performance of the contactor 10, the assembly 14 is removed from the housing 12 and/or second housing section 12B. Another assembly 14 is then inserted in the opening 28 of the housing 12 and fasteners 26 are used to affix the contact switch assembly 14 to the housing 12. Alternatively, if the switching power of the vacuum contactor must be changed, the assembly can be readily removed and replaced. By way of example, assemblies 14 may differ from one another in power switching capabilities so one assembly 14 may include two normally open auxiliary switches, two normally closed auxiliary switches and one common switch. While another assembly may include three normally open auxiliary switches, three normally closed auxiliary switches and one common switch, another assembly 14 may include four normally open auxiliary switches, four normally closed auxiliary switches and one common switch.

As further illustrated in FIGS. 5-7, the assembly frame 20 has a staggered or “split-level” configuration, wherein the circuit board 22 is nested within an upper or first level 20A that overhangs a lower or second level 20B in which the terminals 16, 18 are mounted. Thus, the terminals 16, 18 are recessed relative the first housing level 20A and first housing section 12A to protect the terminals 16, 18 and electrical connects from ambient conditions. To that end, the first housing section 12A is dimensioned to cover the first frame level 20A and the circuit board 22 to protect components of the assembly 14.

Once the assembly 14 is installed, power lines and auxiliary lines are connected to the respective terminals 16, 18. Power input into the vacuum contactor 10 and to the electro-magnetic coil 46 via the plug 40, or electrical connectors 60, 62, energizes the coil 48 which creates a magnetic field actuating rods (of the vacuum bottle assemblies) which are connected to lever 55. The lever 52 pivots opening the contact buses 30, and an arm 54 of the lever 55 closes the auxiliary contact switches 24. When power input is terminated the contact buses 30, and the lever 55 pivots such that the arm 54 is displaced relative to the switches 24 causing the switches to open.

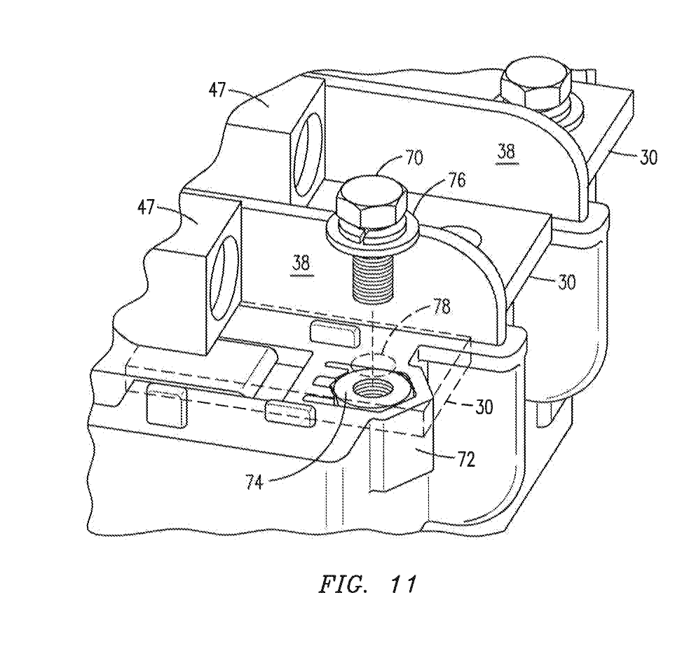

With respect to FIG. 11, the contactor 10 is shown with a bolt 70 and contact bus 30 removed to illustrate a pocket 72 within which a hexagonally shaped nut 74 is positioned. The pocket 72 has a geometric shape corresponding to that of the nut 74 so that surfaces of the pocket 72 and nut 74 interface during attachment of wires to the contact bus 30. More specifically, an electrical wire connection is made between the contact bus 30 and a washer 76 when the bolt 70 inserted through hole 78 and in threaded engagement with the nut 74. In this manner, the electrical connection can be made without having to handle the nut 74 Which can he an awkward task leading to dropping the nut 74. Given the hexagonally shaped pocket 72, the nut 74 with interface with surfaces of the pocket 72 preventing rotation of the nut 74 so that the bolt 70 can be threaded and tightened in place.

While the preferred embodiments of the present invention have been shown and described herein, it will be obvious that such embodiments are provided by way of example only and not of limitation. Numerous variations, changes and substitutions will occur to those skilled in the art without departing from the teaching of the present invention. Accordingly, it is intended that the invention be interpreted within the full spirit and scope of the appended claims.

What is claimed is:

1. An electrical contactor for switching a power circuit, comprising:
a housing in which a plurality of electrical components are housed and connected, and the components comprise at least an electro-magnetic coil,
an opening in the housing and an interior volume in the housing disposed between the opening and the electro-magnetic coil;
a first electrical connector mounted in the housing in electrical communication with the electro-magnetic coil;
an auxiliary switch and control circuit assembly, comprising;
a frame member detachably secured to the housing at the opening;
a circuit board mounted to the frame member supporting a control circuit; and,
a second electrical connector attached to the circuit board and having one or more electrical contacts and the second electrical connector is positioned in mating relationship with the first electrical connector in the housing providing electrical communication between the control circuit and the electro-magnetic coil.

2. The electrical contactor of claim 1, wherein a plurality of auxiliary switches are mounted on the frame member and the circuit board, control circuit and auxiliary switches are disposed in an interior volume of the housing.

3. The electrical contactor of claim 2, wherein the housing has an opening through which the frame member is at least partially insertable and the interior volume in Which circuit board, control circuit and auxiliary switches are disposed is between the opening and the electro-magnetic coil.

4. The electrical contactor of claim 3, wherein the frame of the auxiliary switch and control circuit assembly has a first member on which the circuit board is supported and a second member that is laterally offset inwardly toward the interior volume of the housing relative to the first member.

5. The electrical contactor of claim 4, wherein a power terminal and a plurality of auxiliary terminals are mounted on the second member of the frame member.

6. The electrical contactor of claim 3, wherein the housing includes a first section in which a plurality of bus contacts are contained and the first section of the housing is mounted to a second section which includes the opening to the housing in which the frame member of the auxiliary switch and control circuit assembly is inserted, and the frame member is detachably secured to the second section of the housing.

7. The electrical contactor of claim 6, further comprising a plurality of bus contacts at least partially contained within, the housing and the bus contacts are spaced apart and parallel to one another, and the housing including a plurality of panels including two external panels on the first section of the housing and each external panel is disposed at respective outside edges of the bus contacts and one or more internal panels on the first section of the housing disposed between consecutive bus contacts and the internal panels are longer than the external panels.

8. The electrical contactor of claim 7, wherein the first section of the housing includes a housing mid-section and a cover detachable secured to the mid-section which is disposed between the second section of the housing and the cover, and the internal panels and external panels on the housing cover, and the mid-section has a plurality of internal panels that positioned in mating relationship with corresponding grooves in the internal panels on the cover.

9. The electrical contactor of claim 1, wherein the housing has a generally rectangular base and the electrical contactor further comprises a mounting bracket at each corner of the base and each mounting bracket has an edge that is laterally and outwardly offset relative to a surface of the base to provide a predetermined spacing between adjacent electrical contactors.

10. The electrical contactor of claim 1, wherein the first electrical connection is a projection along a side edge of the circuit board and the second electrical connector is a socket mounted to a surface within an interior volume of the housing.

11. The electrical contactor of claim 1, wherein the first electrical connector is mounted to the circuit board and the second electrical connector is connected to electrical wires and not fixed to a surface within an interior volume of the housing.

12. The electrical contactor of claim 1, further comprising a plurality of contactor buses each having a hole through which a bolt is inserted and connected to a nut for securing an electrical wire to the contact bus, and wherein the housing includes a pocket within which the nut is seated and the pocket has a geometric configuration corresponding to that of the nut to secure the nut and prevent it from rotating when the bolt is threaded there through.

13. A field replaceable auxiliary switch and control circuit assembly for an electrical contactor having a housing in which a plurality of electrical components are housed and operatively connected for switching a power circuit, and the components comprise at least an electro-magnetic coil and an electrical connector disposed in the housing in electrical communication with the electro-magnetic coil, the auxiliary switch and control circuit assembly comprising;
a frame member detachably secured to the housing at an opening in a wall of the housing;
a circuit board mounted to the frame member supporting the control circuit; and,
an electrical connector on the circuit board having one or more electrical contacts and the electrical connector on the circuit is positioned in mating relationship with electrical connector in the housing providing electrical communication between the control circuit and the electro-magnetic coil.

14. The electrical contactor of claim 13, wherein a plurality of auxiliary switches are mounted on the frame member and the circuit board, control circuit and auxiliary switches are disposed in an interior volume of the housing.

15. The electrical contactor of claim 14, wherein the housing has an opening through which the frame member is at least partially insertable and the interior volume in which circuit board, control circuit and auxiliary switches are disposed is between the opening and the electro-magnetic coil.

16. The electrical contactor of claim 15, wherein the frame of the auxiliary switch and control circuit assembly has a first member on which the circuit board is supported and a second member that is laterally offset inwardly toward the interior volume of the housing relative to the first member.

17. The electrical contactor of claim 16, wherein a power terminal and a plurality of auxiliary terminals are mounted on the second member of the frame member.

18. A field replaceable auxiliary switch and control circuit assembly for an electrical contactor, comprising:
a frame member capable of being inserted into and removable from an opening and interior of an electrical contactor housing; and, a circuit board mounted to the frame member and supporting the control circuit.

19. The assembly of claim 18, further comprising an electrical connector on the circuit board having one or more electrical contacts and the electrical connector is capable of being positioned in mating relationship with another electrical connector disposed within the electrical contactor housing.

20. The assembly of claim 18, wherein the frame member has a first member on which the circuit board is supported and a second member that is laterally offset relative to the first member, whereby an outer surface of the first member overhangs an outer surface of the second member.

21. The assembly of claim 20, further comprising a power input terminal on the second frame member that is in electrical communication with the control circuit.

22. The assembly of claim 21, further comprising a plurality of auxiliary switches on the circuit board, which are mounted to the first frame member and that are actuatable to close and open to activate and deactivate the control circuit respectively.

23. The assembly of claim 22, further comprising a plurality of auxiliary terminals on the second frame member in electrical communication with the auxiliary switches.
